(19) United States
(12) Patent Application Publication
(10) Pub. No.: US 2016/0113124 A1
(43) Pub. Date: Apr. 21, 2016

(54) METHOD FOR MANUFACTURING PRINTED CIRCUIT BOARD (PCB)

(71) Applicants: Hyundai Motor Company, Seoul (KR); Kia Motors Corporation, Seoul (KR)

(72) Inventors: Hyung Keun Ko, Pyeongtaek (KR); Mun Jong Kim, Suwon (KR); Yang Yoon Choi, Gyeongsan (KR); Kyung Jeon Pakr, Bucheon (KR); Hyun Taek Hwang, Incheon (KR)

(21) Appl. No.: 14/695,639

(22) Filed: Apr. 24, 2015

(30) Foreign Application Priority Data
Oct. 21, 2014 (KR) 10-2014-0142904

(51) Int. Cl. H05K 3/46; H05K 3/00

(52) U.S. Cl. CPC H05K 3/46; H05K 3/0091

(57) ABSTRACT

A method for forming a printed circuit board (PCB) includes: depositing, a first time, a photo imageable solder resist (PSR) ink over a top surface and a bottom surface of the PCB including a conductive pattern; drying, a first time, the PCB on which the PSR ink has been deposited for the first time; depositing, a second time, the PSR ink over the top surface and the bottom surface of the PCB; and drying, a second time, the PCB on which the PSR ink has been deposited for the second time.

### CROSS-REFERENCE TO RELATED APPLICATION

This application claims the benefit of and priority to Korean Patent Application No. 10-2014-0142904 filed on Oct. 21, 2014, the disclosure of which is hereby incorporated in its entirety by reference.

### TECHNICAL FIELD

Embodiments of the present disclosure relate to a method for manufacturing a printed circuit board (PCB), and more particularly, to a technology for depositing Photo imageable Solder Resist (PSR) to a PCB.

### BACKGROUND

General printed circuit boards (PCBs) for use in vehicles have a disadvantage in that inner heat flow property can be deteriorated. In order to overcome the inner heat flow deterioration phenomenon, methods for increasing thermal diffusion by inserting a metal material into the PCB have been widely used. Copper(Cu) patterns have been used to increase thermal diffusion, causing product costs to increase due to the increasing expenses of copper raw material. In order to address the above-mentioned cost problem, circuit patterns have been formed of cheap aluminum (Al).

Aluminum (Al) has a lower electrical conductivity than copper (Cu), and thus, aluminum (Al) requires a larger-sized area than a cross section of a conventional copper (Cu) pattern. If the cross section of an aluminum (Al) pattern increases, the size of products is also increased. Therefore, it is common to fix an upper width of the aluminum pattern and adjust a thickness of the aluminum pattern so as to increase a cross section thereof.

As the aluminum pattern becomes thicker, it also becomes deeper. As a result, the conventional ink coating method has a disadvantage in that the aluminum pattern may peel off or bubbles may occur. Therefore, in order to address the above-mentioned problem, a method for stably applying ink to a depth of the aluminum pattern is needed.

### SUMMARY

Various embodiments of the present disclosure are directed to providing a method for manufacturing a printed circuit board (PCB) that substantially obviates one or more problems due to limitations and disadvantages of the related art. Embodiments of the present disclosure relate to a method for stably depositing a Photo imageable Solder Resist (PSR) although a circuit pattern formed on the PCB increases in thickness.

According to embodiments of the present disclosure, a method for forming a printed circuit board (PCB) includes: depositing, a first time, a photo imageable solder resist (PSR) ink over a top surface and a bottom surface of the PCB including a conductive pattern; drying, a first time, the PCB on which the PSR ink has been deposited for the first time; depositing, a second time, the PSR ink over the top surface and the bottom surface of the PCB; and drying, a second time, the PCB on which the PSR ink has been deposited for the second time.

The method may further include removing a foreign material from the top surface and the bottom surface of the PCB prior to the first deposition of the PSR ink.

The first drying of the PCB and the second drying of the PCB may be carried out at a temperature of approximately 50˜80° C. for about 15˜25 minutes.

The second depositing of the PSR ink may include depositing the PSR ink over the firstly deposited PSR

The method may further include performing an exposure and development process after the second drying of the PCB.

The method may further include drying, a third time, the PCB after performance of the development process.

The third drying of the PCB may be carried out at a temperature of approximately 140˜170° C.

The PCB may include a cutting line disposed between a plurality of regions and a protruded jig in the cutting line.

The PSR ink may be deposited using a screen scheme.

The conductive pattern may include aluminum.

It is to be understood that both the foregoing general description and the following detailed description of the present disclosure are exemplary and explanatory and are intended to provide further explanation of the embodiments as claimed.

### BRIEF DESCRIPTION OF THE DRAWINGS

FIG. 1 is a flowchart illustrating a conventional method for depositing ink over a printed circuit board (PCB).

FIG. 2 is a flowchart illustrating a method for depositing ink over the PCB according to embodiments of the present disclosure.

FIGS. 3A to 3H are cross-sectional views illustrating a method for depositing ink over the PCB according to embodiments of the present disclosure.

FIGS. 4A to 4C illustrate a screen scheme from among ink deposition methods for PCBs according to embodiments of the present disclosure.

It should be understood that the above-referenced drawings are not necessarily to scale, presenting a somewhat simplified representation of various preferred features illustrative of the basic principles of the disclosure. The specific design features of the present disclosure, including, for example, specific dimensions, orientations, locations, and shapes, will be determined in part by the particular intended application and use environment.

### DETAILED DESCRIPTION OF EMBODIMENTS

Reference will now be made in detail to embodiments of the present disclosure, examples of which are illustrated in the accompanying drawings. Wherever possible, the same reference numbers will be used throughout the drawings to refer to the same or like parts.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

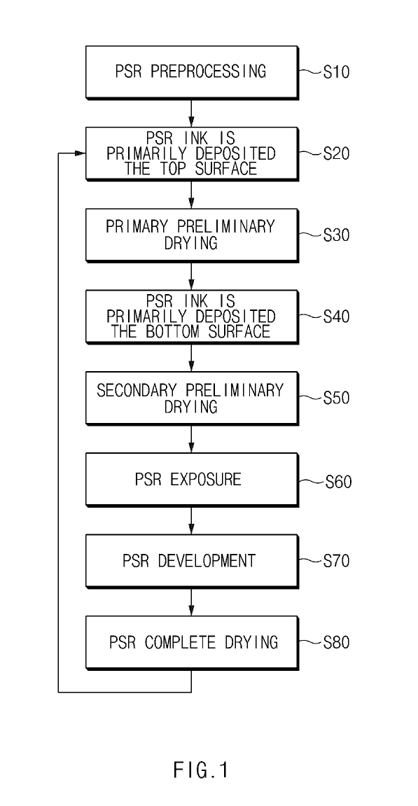

FIG. 1 is a flowchart illustrating a conventional method for depositing PSR ink over the PCB. Referring to FIG. 1, PSR preprocessing is applied on the PCB having a conductive pattern in step S10. PSR ink is deposited over the PCB in step S20. Thereafter, preliminary drying, a first time, is processed on the resultant PCB in step S30.

PSR ink is deposited a second time over a bottom surface of the PCB in step S40. Therefore, preliminary drying, a second time, is processed on the resultant PCB in step S50. Subsequently, a PSR exposure process is performed on the PCB in step S60, and the PSR development process is then performed thereon in step S70. Thereafter, a complete drying process is performed on the PCB in step S80.

In accordance with the PSR ink deposition process, PSR ink can be deposited once over each surface according to the one-surface deposition scheme. Therefore, in order to fill a thick pattern such as the aluminum pattern, the above-mentioned processes should be repeatedly performed. If the above-mentioned processes are repeatedly performed, as described above, product costs unavoidably increase and productivity and reliability may be deteriorated.

In order to address the above-mentioned problem, a method for increasing ink thickness without repeating the above processes based on double-sided printing has been proposed.

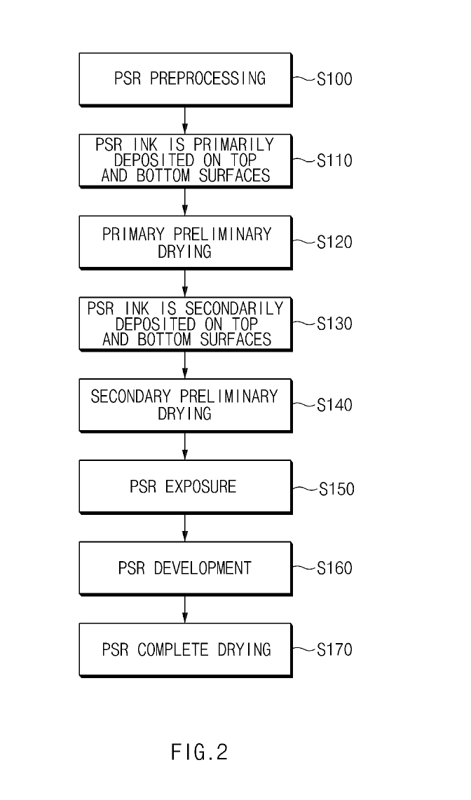

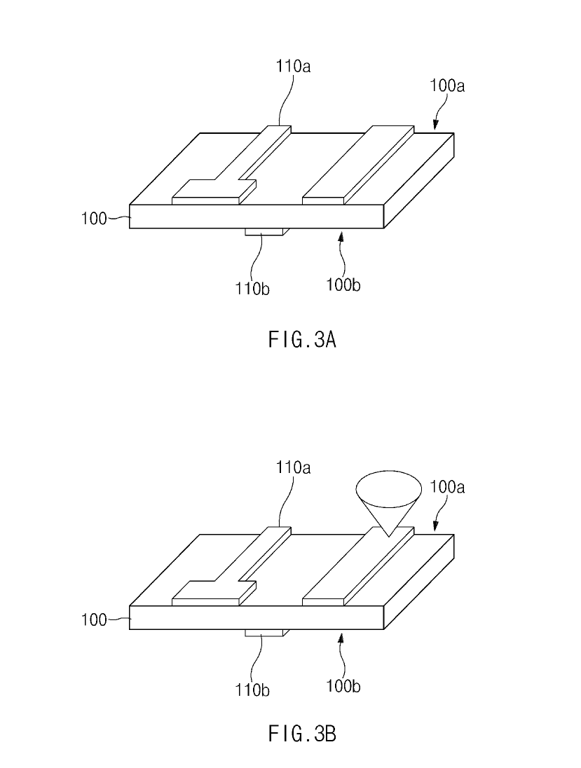

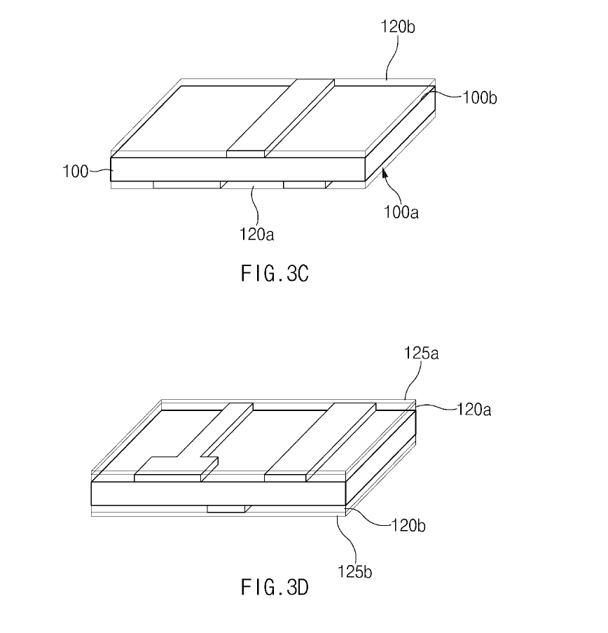

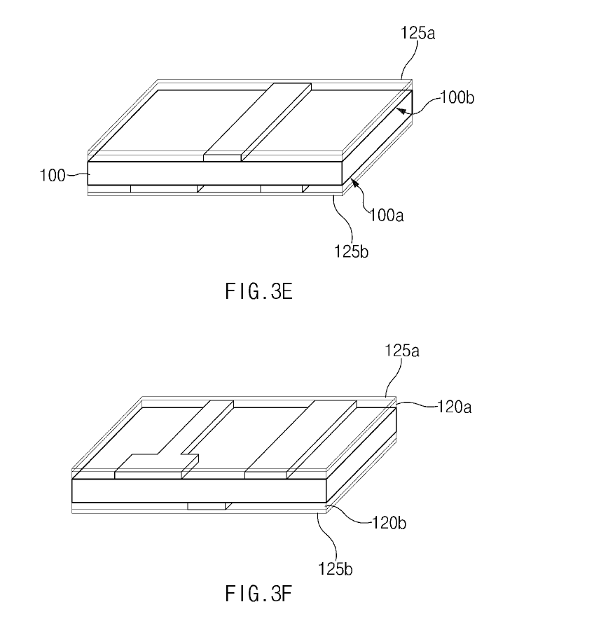

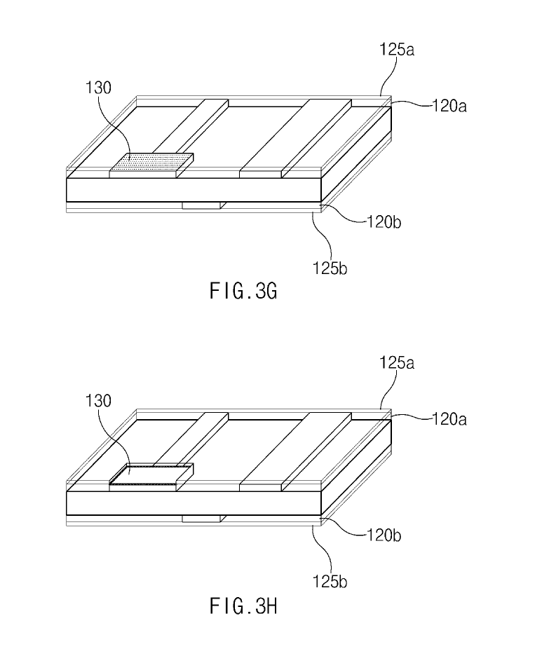

FIG. 2 is a flowchart illustrating a method for depositing ink over the PCB according to embodiments of the present disclosure. FIGS. 3A to 3H are cross-sectional views illustrating a method for depositing ink over the PCB according to the method shown in FIG. 2. A method for depositing ink over the PCB according to the present disclosure will hereinafter be described with reference to FIGS. 2 and 3A to 3H.

Referring to FIG. 3A, a conductive pattern 110a is formed over a top surface 100a of a substrate 100, and a conductive pattern 110b is formed over a bottom surface 100b of the substrate 100. The conductive patterns (110a, 110b) may be formed of aluminum. Thereafter, the PSR preprocessing is performed over the substrate 100 including the conductive patterns (110a, 110b) in step S100. The PSR preprocessing includes removing a foreign material from the top surface 100a and the bottom surface 100b, and forming roughness on the surface of the substrate 100. When the PSR ink deposition is performed through this processing, such that adhesive force between the substrate and the PSR ink can be increased.

Referring to FIG. 3B, the PSR ink is deposited, a first time, over the top surface 100a and the bottom surface 100b of the substrate 100 in step S110. The PSR ink deposition step may be performed by the screen printing scheme or the printer.

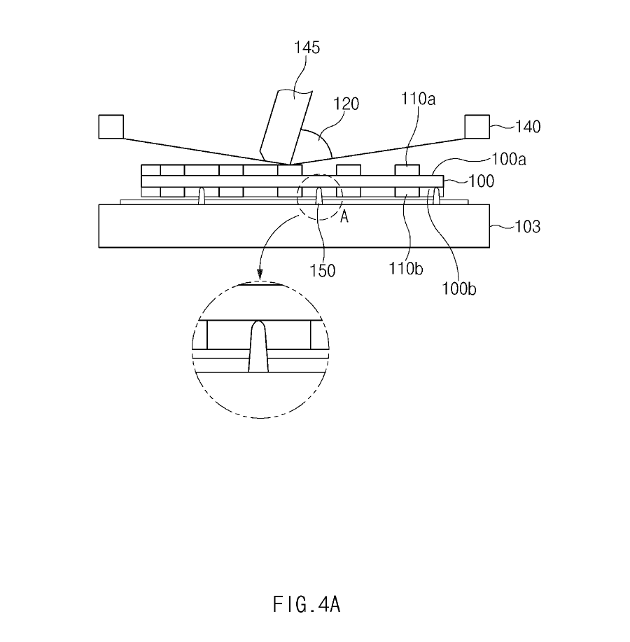

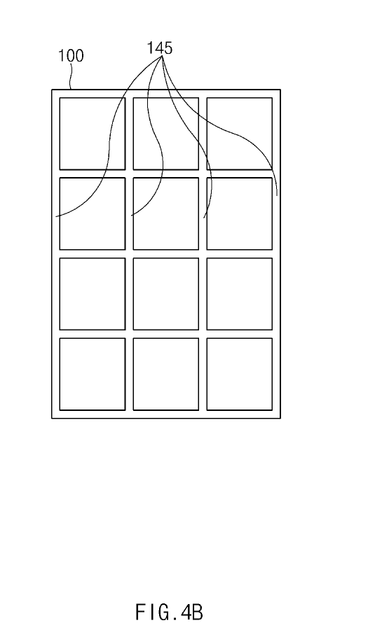

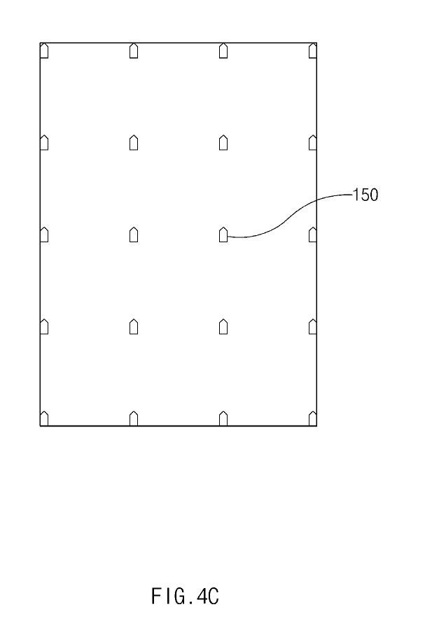

The screen printing scheme will hereinafter be described with reference to FIG. 4A. The screen printing may transfer a wiring pattern, that is formed over the screen 140 formed by weaving of microfibers formed of silk, Teflon, polyester, nylon, or the like, to the PCB substrate 100. In accordance with the screen printing scheme, the remaining part other than a specific part in which the wiring pattern is formed over the screen may be formed of a mesh (net), or the remaining part other than the specific part having the wiring pattern is filled with emulsion, the PSR ink 120 is poured thereon, the PSR ink 120 is pushed by a squeeze 145, and the PSR ink 120 passes through the screen, so that a predetermined wiring pattern is formed on the PCB substrate 100.

The PSR ink deposition step includes depositing the PSR ink on the top surface 100a of the substrate, and depositing ink on the bottom surface 100b before drying the resultant substrate. Conventionally, the PSR ink can be deposited over one surface through only one deposition. However, jigs 150 (e.g., see FIGS. 4A and 4B) acting as fixed pins may be formed in the last cutting line, so that the jigs 150 can be spaced apart from a table 103 by a predetermined distance. Therefore, when squeeze rubber operates, the substrate is not in contact with the table. As a result, although the ink is deposited over the top surface 100a of the PCB substrate 100 and the substrate is then turned over so as to deposit the ink over the bottom surface of the substrate, no ink remains over the table.

Referring to FIG. 3C, a first drying process is performed on the PCB substrate 100 on which the PSR inks (120a, 120b) are deposited. The first drying process is a preliminary drying process in which the drying process can be carried out at a temperature of approximately 50˜80° C. for approximately 15˜25 minutes. In the first preliminary drying process, the drying process is temporarily performed prior to execution of the complete drying, so that the substrate can be easily handled. In addition, if the ink is deposited over a specific part in which the ink is prevented from being deposited, the ink can be easily removed from unnecessary parts during the preliminary drying process.

Referring to FIG. 3D, the PSR ink 125a is deposited over the top surface 100a of the PCB substrate 100 over which the PSR ink 120a is deposited for the first time, and the PSR ink 125b is deposited over the bottom surface 100b of the PCB substrate 100 over which the PSR ink 120b is deposited for the first time in step S130. Since the first drying process is performed after deposition of the first PSR inks (120a, 120b), second PSR inks (125a, 125b) are deposited over the dried PSR inks (120a, 120b). That is, the PSR ink deposition thickness can be increased without repeating the PSR ink deposition process as shown in FIG. 1.

Referring to FIG. 3E, a second drying process is performed on the PCB substrate 100 over which the PSR inks (125a, 125b) are deposited for the second time in step S140. The second drying process can be performed in the same manner as in the first drying process. For example, the second drying process may be carried out at a temperature of approximately 50˜80° C. for approximately 15˜25 minutes.

Referring to FIG. 3F, an exposure process is performed on the PCB substrate 100 to which a second drying process has been applied in step S150. The exposure process may be performed by illuminating ultraviolet (UV) light onto the PCB substrate 100, and the PSR ink is hardened by the UV light. In this case, a specific part to be exposed may prevent UV light through an exposure mask. The part in which the UV light is blocked is not hardened.

Referring to FIG. 3G, the PCB substrate 100 on which the exposure process has been performed may be developed. During the development process, the un-hardened part 130 is removed by the developer, and only the hardened part remains unchanged, resulting in formation of a predetermined circuit pattern.

Referring to FIG. 3H, the PCB substrate 100 on which the development process has been performed is dried, a third time, in step S170. The third drying step indicting the complete drying step may be performed at a temperature of 140˜170° C. In the third drying step, a solvent contained in the PSR ink is completed removed so that the PCB substrate 100 is finally dried.

As is apparent from the above description, the method for forming the PCB according to embodiments of the present disclosure involves depositing ink twice (i.e., a first and second deposition) by successively printing a top surface and a bottom surface of the PCB, thereby increasing the thickness of the deposited ink without repeating respective processes. Therefore, a fabrication time for depositing PSR ink over the PCB can be shortened and product reliability can be increased.

Although the embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A method for forming a printed circuit board (PCB) comprising:
depositing, a first time, a photo imageable solder resist (PSR) ink over a top surface and a bottom surface of the PCB including a conductive pattern;
drying, a first time, the PCB on which the PSR ink has been deposited for the first time;
depositing, a second time, the PSR ink over the top surface and the bottom surface of the PCB; and
drying, a second time, the PCB on which the PSR ink has been deposited for the second time.

2. The method according to claim 1, further comprising:
removing a foreign material from the top surface and the bottom surface of the PCB prior to the first deposition of the PSR ink.

3. The method according to claim 1, wherein the first drying of the PCB and the second drying of the PCB are carried out at a temperature of approximately 50˜80° C. for about 15˜25 minutes.

4. The method according to claim 1, wherein the second depositing of the PSR ink includes:
depositing the PSR ink over the firstly deposited PSR.

5. The method according to claim 1, further comprising:
performing an exposure and development process after the second drying of the PCB.

6. The method according to claim 5, further comprising:
drying, a third time, the PCB after performance of the development process.

7. The method according to claim 6, wherein the third drying of the PCB is carried out at a temperature of approximately 140˜170° C.

8. The method according to claim 1, wherein the PCB includes a cutting line disposed between a plurality of regions and a protruded jig in the cutting line.

9. The method according to claim 1, wherein the PSR ink is deposited using a screen scheme.

10. The method according to claim 1, wherein the conductive pattern includes aluminum.
